(19) United States
(12) Patent Application Publication
(10) Pub. No.: US 2026/0198264 A1
(43) Pub. Date: Jul. 9, 2026

(54) PLASMA PROCESSING APPARATUS AND PLASMA PROCESSING METHOD

(71) Applicant: Hitachi High-Tech Corporation, Minato-ku, Tokyo (JP)

(72) Inventors: Ryu EZAKI, Tokyo (JP); Kosa HIROTA, Tokyo (JP); Kazuyuki IKENAGA, Tokyo (JP); Masahiro SUMIYA, Tokyo (JP)

(21) Appl. No.: 18/838,763

(22) PCT Filed: Aug. 23, 2023
(86) PCT No.: PCT/JP2023/030363

§ 371 Date: Aug. 15, 2024

(51) Int. Cl. H10P 72/72; H01J 37/32; H10P 34/40

(52) U.S. Cl. CPC H10P 72/72; H01J 37/32715; H10P 34/40; H01J 37/32082; H01J 2237/2007

(57) ABSTRACT

A plasma processing apparatus and method which prevents adhesion of charged particles to a sample in plasma etching processing, including a plasma processing chamber, a radio frequency power supply for generating the plasma, an electrostatic attraction electrode configured to apply a voltage to the sample to electrically attract and fix the sample, and a direct current power supply configured to apply a voltage to the electrostatic attraction electrode, the plasma processing method including an ignition step of generating the plasma by the radio frequency power supply from the sample placed on the electrostatic attraction electrode, a plasma discharge step of performing etching of the sample, and a dechuck step of releasing the attracting and fixing by dechuck after the plasma discharge step, in which the voltage applied to the electrostatic attraction electrode of the sample is larger than 0 V from the ignition step to the dechuck step.

### TECHNICAL FIELD

The present invention relates to a semiconductor device manufacturing technique, and more particularly relates to a plasma processing apparatus and a plasma processing method suitable for preventing adhesion of particles during plasma etching processing.

### BACKGROUND ART

In recent years, semiconductor device development has continued to move toward a direction of miniaturization and higher integration of circuits as indicated in roadmaps typified by international roadmap for devices and systems (IRDS). In such a trend, a semiconductor manufacturing device is required to have higher device specs than ever before in terms of both processing accuracy and mass productivity. The prevention of adhesion of particles to a sample substrate (wafer) is also considered as one of demands, and as a pitch width of the semiconductor device is reduced, a particle having a small particle size which has been ignored up to now becomes a factor of processing defects. Specifically, as of 2025, since non-electrically active particles having a particle size ≥7 nm are expected to have an impact as critical particles, measures to prevent the adhesion of these foreign particles to wafers will become important in the future.

Such a particle problem is particularly important in plasma etching, which is used in etching processing on a sample in semiconductor manufacturing. In the plasma etching, after a wafer is placed on a sample stage inside a processing chamber, electrostatic attraction for preventing a positional deviation of the wafer is performed, and the wafer is exposed to plasma. At this time, by adjusting various processing conditions such as a gas type to be introduced into the processing chamber and radio frequency power to be applied to the wafer, a specific stacked film on the wafer is selectively removed to form a fine circuit pattern on the wafer. When a particle adheres to the wafer during the plasma processing described above, since a fatal defect in the semiconductor device may occur due to a disconnection or a short circuit in a wiring, there is currently a need to reduce particles to improve yield.

Under the current circumstances described above, a technique for preventing the adhesion of a charged particle to a wafer front surface, which easily occurs in the plasma processing apparatus has been proposed so far. For example, in PTL 1, an electrostatic attraction method is proposed in which a voltage applied to a wafer from an electrostatic attraction electrode is adjusted to be constant in electrostatic attraction of the wafer, and a surface voltage of the wafer is brought close to 0 V to prevent the aspiration of the charged particle to the wafer. £ However, in the above-described electrostatic attraction method, the wafer may be negatively charged due to an inflow of floating charges into the wafer during the etching processing, and a charged state is not pulled back to 0 V after interruption of plasma discharge. Since the yield may deteriorate when the charged particle in a sample chamber is attracted to the wafer due to the above-described wafer charging, it is desirable to eliminate negative charging of the wafer. In the plasma etching processing, a method disclosed in PTL 2 is proposed as an electrostatic attraction method for preventing negative charging of a wafer.

In PTL 2, due to an inflow of floating charges into the wafer during plasma processing on the wafer, a surface voltage of the wafer changes in a negative direction, and after the plasma processing is finished, the surface voltage of the wafer tends not to return to a 0 V state before processing is stared. Regarding this, a technique is disclosed in which during the plasma discharge processing step of the wafer, an applied voltage to the wafer is shifted in a negative direction by a first shift amount to have the same magnitude as the wafer potential change amount caused by the inflow of the floating charges, and after the plasma discharge processing is finished, the direct current voltage shifted by the first shift amount in the negative direction is shifted in a positive direction by a second shift amount to cancel the charging of the wafer due to the floating charges.

### CITATION LIST

### Patent Literature

PTL 1: WO2009/013803A

PTL 2: JP2016-213358A

### SUMMARY OF INVENTION

### Technical Problem

In PTL 1, the applied voltage for the electrostatic attraction of the wafer is changed during the plasma etching processing, but the present control method does not consider current generation in the wafer due to a rapid fluctuation in the applied voltage. During the plasma etching processing, a generation state of the plasma may become unstable due to the rapid fluctuation in the current in the wafer. When a state of the plasma is unstable, abnormal discharge is induced, which causes the generation of particles. Therefore, it is not desirable to rapidly change parameters such as the applied voltage.

In the technique disclosed in PTL 2, the charging of the wafer due to floating charges can be canceled, but it can be understood that an effect of preventing the adhesion of particles is not sufficient from studies conducted by the present inventors.

An object of the invention is to provide a plasma processing apparatus and a plasma processing method capable of preventing attraction of a charged particle to a wafer and reducing adhesion of the particle to the wafer while maintaining a stable generation state of plasma.

### Solution to Problem

The invention is a plasma processing apparatus including: a processing chamber configured to allow a sample to be plasma-processed therein using plasma; a radio frequency power supply configured to supply radio frequency power for generating the plasma; a sample stage including an electrode to which a voltage for electrostatically attracting the sample is applied and configured to allow the sample to be placed thereon; a direct current power supply configured to apply the voltage to the electrode; and a control device configured to control the direct current power supply to apply a positive voltage to the electrode in a period from ignition of the plasma until the sample is separated from the sample stage.

### Advantageous Effects of Invention

A plasma processing apparatus and a plasma processing method capable of preventing attraction of a charged particle to a wafer and reducing adhesion of particles to the wafer while maintaining a stable generation state of plasma can be provided.

### BRIEF DESCRIPTION OF DRAWINGS

FIG. 1 is a schematic view illustrating a configuration of a plasma processing apparatus according to the invention.

FIG. 2 is a time chart of processing according to Embodiment 1 of the invention.

FIG. 3 is a time chart illustrating Existent Example 1.

FIG. 4 illustrates a result of an investigation regarding effect of reducing particle adhesion to a wafer according to Embodiment 1.

FIG. 5 is a time chart of processing according to Embodiment 2 of the invention.

FIG. 6 is a time chart of processing according to a development example of Embodiment 2 of the invention.

FIG. 7 illustrates a result of an investigation regarding an effect of reducing particle adhesion to a wafer according to Embodiment 2.

FIG. 8 is a time chart of processing according to Embodiment 3 of the invention.

FIG. 9 illustrates a result of an investigation regarding an effect of reducing particle adhesion to a wafer according to Embodiment 3.

FIG. 10 is a time chart of processing according to Embodiment 4 of the invention.

FIG. 11 is a time chart illustrating Existent Example 2.

FIG. 12 illustrates a result of an investigation regarding an effect of reducing particle adhesion to a wafer according to Embodiment 4.

### DESCRIPTION OF EMBODIMENTS

Hereinafter, embodiments of the invention will be described with reference to the drawings. The following description is only Embodiments, and the scope of rights in the present application is not limited to these embodiments.

### Embodiment 1

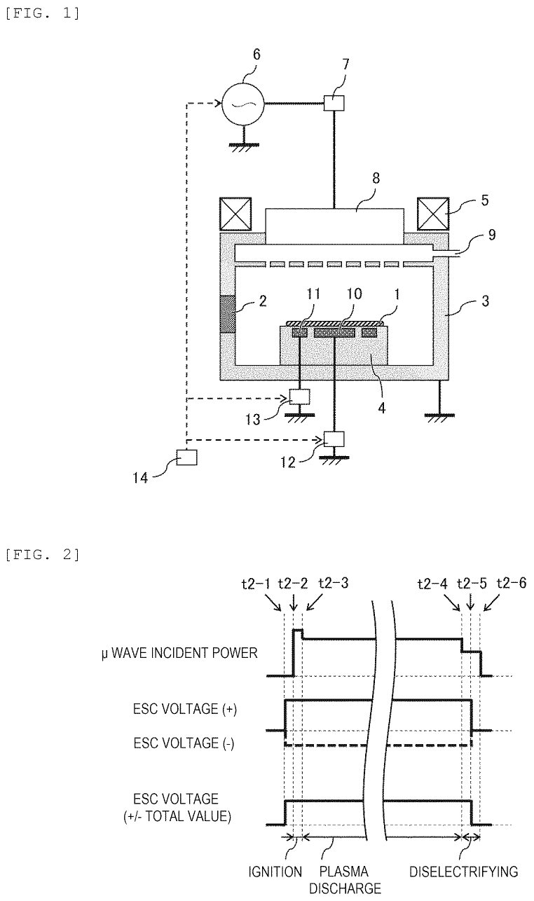

Embodiment 1 of the invention will be described with reference to FIGS. 1 to 4. First, a plasma processing apparatus for implementing the invention will be described with reference to FIG. 1. FIG. 1 is a schematic view illustrating a configuration of the plasma processing apparatus according to the invention.

In the plasma processing apparatus used in the present embodiment, a wafer 1, which is a semiconductor substrate serving as a sample, is carried into a processing chamber 3, which is a vacuum processing chamber, from a gate 2 for wafer transfer, and is placed on a sample stage 4 for wafer placement.

The present plasma processing apparatus includes a solenoid coil 5, a radio frequency power supply 6 for generating a μ wave, a μ wave oscillation source 7, a resonance unit 8, and a gas supply unit 9 as mechanisms for generating plasma. In the processing apparatus, a magnetic field is generated by the solenoid coil 5. The μ wave generated by the μ wave oscillation source 7 from radio frequency power from the radio frequency power supply 6 is introduced into the processing chamber 3 via the resonance unit 8. The μ wave provides energy to electrons in the magnetic field generated by the solenoid coil 5. The electrons generate the plasma by ionizing a gas supplied from the gas supply unit 9.

During the plasma processing, a cooling gas for adjusting a temperature of the wafer 1 is supplied to a back surface of the wafer 1. To prevent a deviation of the wafer 1 caused by the cooling gas, the wafer 1 is attracted to the sample stage 4 by bipolar electrostatic attraction electrodes 10 and 11 which are electrodes having different polarities. The electrostatic attraction electrodes 10 and 11 are arranged concentrically, with one electrode 10 on an inside and the other electrode 11 on an outside.

Direct current power supplies 12 and 13, which are independent power supplies, are connected to the electrostatic attraction electrodes (hereinafter, may be referred to as ESCs) 10 and 11, respectively. The direct current power supply 12 is connected to the electrostatic attraction electrode 10 on the inside, and the direct current power supply 13 is connected to the electrostatic attraction electrode 11 on the outside.

Although the electrostatic attraction electrode and the wafer are insulated from each other, when a positive voltage is applied to the electrostatic attraction electrode, a negative charge is generated on the wafer back surface close to the electrode, and the wafer is attracted by the electrode by the Coulomb force. Conversely, when a negative voltage is applied, a positive charge is generated on the wafer back surface.

When the negative charge is generated on the wafer back surface, the positive charge is generated on a wafer front surface facing the back surface, and a potential of the entire wafer becomes zero. Conversely, when the positive charge is generated on the wafer back surface, the negative charge is generated on the wafer front surface facing the back surface.

Voltages having opposite polarities are applied to the electrostatic attraction electrodes 10 and 11 from the direct current power supplies, respectively. For example, a voltage of +800 V is applied to the electrostatic attraction electrode 10 on the inside from the direct current power supply 12, and a voltage of −200 V is applied to the electrostatic attraction electrode 11 on the outside from the direct current power supply 13.

As the inventors investigated, the inventors have found that the adhesion of the particle to the wafer front surface can be prevented by applying a voltage to the electrostatic attraction electrode under a condition where a total value ((+800 V)+(−200 V)=(+600 V) in the case described above. Hereinafter, the voltage will be defined as a sum of applied voltages.) of the voltages applied to the electrostatic attraction electrodes is positive. The theory is that since the positive charge proportional to +800 V is generated on the wafer front surface facing the electrostatic attraction electrode 10 on the inside and the negative charge proportional to −200 V is generated on the wafer front surface facing the electrostatic attraction electrode 11 on the outside, a positive charge is generated on the wafer front surface on average, and the particle, which is often positively charged, is forced to move in a direction away from the wafer front surface due to the Coulomb force. Results of experiments conducted by the inventors will be described below.

The present plasma processing apparatus includes a control device 14 for controlling output values of the direct current power supplies 12 and 13. The variable direct current power supplies 12 and 13 are connected to the control device 14, and the output value of the voltage is controlled by the control device 14. The control device 14 is further connected to the radio frequency power supply 6 for generating a μ wave, and controls the power output value and a timing output switching from the radio frequency power supply 6.

Here, in a configuration example of the present plasma processing apparatus, as described above, bipolar electrostatic attraction electrodes are used to perform the electrostatic attraction on the wafer using two different direct current power supplies, but even a single-polar electrostatic attraction electrode with one electrode connected to the ground may be used. When a single-polar attraction electrode is used, an apparatus configuration can be further simplified, and the design difficulty and manufacturing cost of the plasma processing apparatus can be reduced. In addition, a multi-polar electrostatic attraction electrode that performs the electrostatic attraction on the wafer using three or more direct current power supplies may be used. When a multi-polar electrostatic attraction electrode is used, the voltage applied to the wafer can be controlled locally, and a distribution of plasma can be adjusted.

FIG. 2 is a time chart of processing according to Embodiment 1 of the invention. Contents of the invention will be described using a time chart. A plasma processing process illustrated in FIG. 2 has three steps including an ignition step performed from t2-1 to t2-3, a plasma discharge step performed from t2-3 to t2-4, and a dechuck step performed from t2-4 to t2-6. The “μ wave incident power” in FIG. 2 is radio frequency power from the radio frequency power supply above the processing chamber, the “ESC voltage (+)” is the positive voltage output from the direct current power supply 12, and the “ESC voltage (−)” is the negative voltage output from the direct current power supply 13.

In the present embodiment, before a timing of t2-1 illustrated in FIG. 2, first, the wafer 1 is carried into the processing chamber 3 and placed on the sample stage 4. Next, at the timing of t2-1, the positive voltage and the negative voltage are simultaneously output from the direct current power supplies 12 and 13 to the electrostatic attraction electrodes 10 and 11, respectively, and the wafer 1 is attracted to the sample stage 4.

Here, the present inventors have found that the number of particles can be reduced when a net applied voltage to the electrostatic attraction electrode is +1 V or more. To stably attract the wafer, a potential difference between the electrodes is preferably set to a value of 1000 V or more from a viewpoint of maintaining an electrostatic attraction force of the wafer. In the present embodiment, the ESC voltage (+) is set to +800 V, and the ESC voltage (−) is set to −200 V, that is, the net applied voltage is set to +600 V to perform the processing. Next, when the power of 1000 W is supplied from the radio frequency power supply 6 at a timing of t2-2 at which the ignition step is started, the plasma is generated in the processing chamber 3 by causing a current to flow through the solenoid coil 5. The supplied power herein is set to be higher than the power used in normal plasma etching processing to prevent misfires of the plasma ignition. Subsequently, at a timing of t2-3, the power supplied from the radio frequency power supply is changed to 800 W, and the plasma discharge step is started.

Next, at a timing of t2-4 at which the dechuck step is started, the power supplied from the radio frequency power supply is changed to 450 W, and an output of the plasma discharge is gradually reduced. Subsequently, at a timing of t2-5, the voltage supplied from the direct current power supply to the electrostatic attraction electrode is changed to 0 V, and the electrostatic attraction is stopped. Finally, at a timing of t2-6, the power supplied from the radio frequency power supply is changed to 0 W to finish the dechuck step (hereinafter, also referred to as a dechuck step).

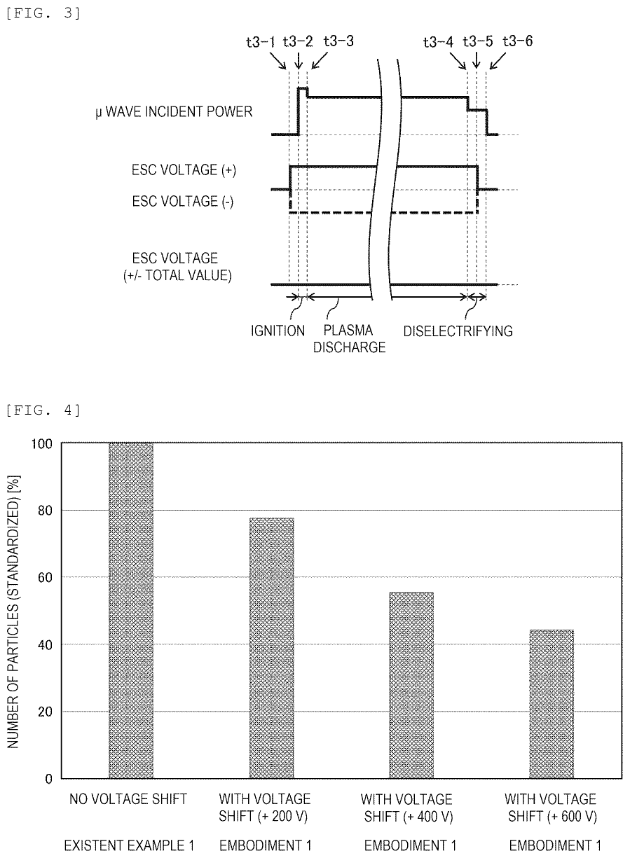

With respect to the above-described Embodiment 1, a plasma processing process in Existent Example 1 for level comparison of the particle reduction effect will be described. FIG. 3 illustrates a time chart of processing in the related art corresponding to Existent Example 1. Existent Example 1 is a plasma processing process in which during a period of t3-1 to t3-6, voltage values of the ESC voltage (+) and the ESC voltage (−) are set to +500 V and −500 V, respectively, and a net applied voltage at the time of electrostatic attraction is changed to 0 V.

For Embodiment 1 and Existent Example 1 described above, an evaluation experiment on the number of particles adhering to the wafer after the plasma etching processing was performed. In the experiment, the pressure inside the processing chamber 3 was set to 0.5 Pa, and a mixed gas of Ar and O₂ was continuously supplied into the chamber from when the ignition step was started to a timing at which the dechuck step was finished. A flow rate of Ar was 100 ml/min, and a flow rate of O₂ was 30 mL/min. A temperature of the sample stage 4 was set to 50° C., He was used as a back gas for cooling the wafer, and the supply of the gas was maintained such that the pressure on the back surface was maintained at 2 kPa.

In the present experiment, the plasma etching processing described above was performed 30 times or more under each condition, the number of particles adhering to the wafer in each implementation was counted, and a median value of the number of adhering particles under each condition was compared. In the present experiment, a target particle diameter of the particle was 0.025 μm or more.

FIG. 4 illustrates a result of an investigation regarding an effect of reducing the particle adhesion to the wafer according to Embodiment 1. A vertical axis of FIG. 4 is a converted value of the number of adhering particles when the number of adhering particles in Existent Example 1 is standardized as 100%. In FIG. 4, to illustrate a correlation between the applied voltage to the wafer and the number of particles adhering to the wafer, results of investigation when the ESC voltage (+) is set to +600 V and the ESC voltage (−) is set to −400 V, that is, the net applied voltage is set to +200 V, and when the ESC voltage (+) is + set to 700 V and the ESC voltage (−) is set to −300 V, that is, the net applied voltage is set to +300 V from t2-1 to t2-5 are also illustrated simultaneously. As can be understood from the result, in the plasma processing process in Embodiment 1 in which the total value of the applied voltages for electrostatic attraction was maintained at a positive value from t2-1 to t2-5, the number of particles decreased as the net applied voltage increased. Further, based on the result of Comparative Example 1 when the net applied voltage is set to +600 V, the number of particles can be reduced to half or less compared to that of Embodiment 1.

### Embodiment 2

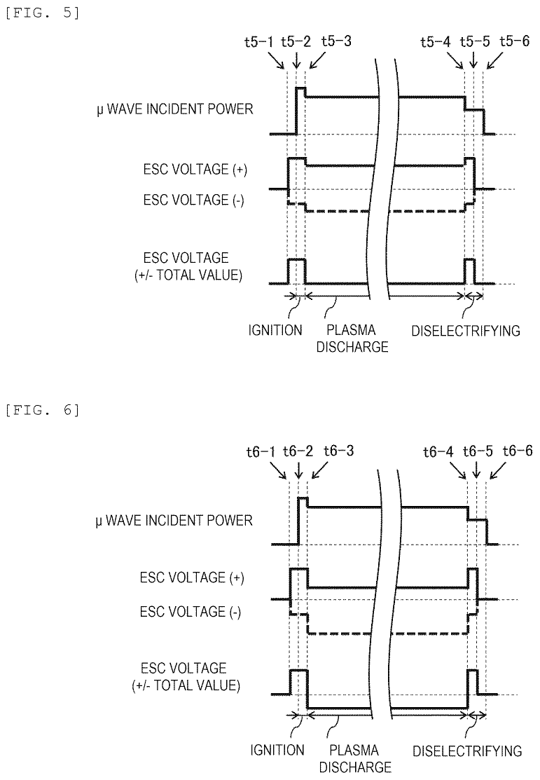

FIG. 5 is a time chart of processing according to Embodiment 2 of the invention. Embodiment 2 of the invention will be described while paying attention to a difference in configuration from Embodiment 1. In FIG. 5, in a period from t5-3 to t5-4, a total value of net applied voltages to electrostatic attraction electrodes is changed to 0 V and is changed from +600 V, which is an adopted value in Embodiment 1 described above. Operation conditions in a period before t5-3 and a period after t5-4 in FIG. 5 are the same as those in a period before t2-3 and a period after t2-4 in the plasma processing process (FIG. 2) according to Embodiment 1 described above. Therefore, the description thereof will be omitted.

As illustrated in FIG. 5, in the present embodiment, at a timing of t5-3, the voltage value for electrostatic attraction is changed such that the net applied voltage from the direct current power supplies 12 and 13 to the electrostatic attraction electrode becomes 0 V. In the present embodiment, to prevent the reduction of the electrostatic attraction force of the wafer, the voltage values of the ESC voltage (+) and the ESC voltage (−) are set to +600 V and −600 V, respectively, and a potential difference between both electrodes is maintained at 1200 V. By controlling the applied voltage in this manner, it is possible to prevent the rapid parameter changes that occur in the adoption processing in PTL 2, and as a result, it is possible to prevent a fluctuation in the etching processing caused by changes in plasma distribution due to changes in wafer potential. Subsequently, at a timing of t5-4, the total value of the net applied voltages to the electrostatic attraction electrodes is changed to a positive value again, thereby being capable of preventing the adhesion of charged particles as described above.

In the present embodiment, the total value of the net applied voltages to the electrostatic attraction electrodes in the plasma discharge step from t5-3 to t5-4 is set to 0 V. However, a plasma potential of the wafer may be shifted in the negative direction due to the inflow of floating charges during the present period. For this, as a development example from Embodiment 2, the net applied voltage to the electrostatic attraction electrode during the period may be set to a value shifted in the negative direction by a shift amount of the plasma potential. FIG. 6 illustrates a time chart of processing according to the development example of Embodiment 2 of the invention. Hereinafter, the present development example will be described while paying attention to a difference in configuration from Embodiment 2.

In FIG. 6, in a period from t6-3 to t6-4, the total value of the net applied voltages to the electrostatic attraction electrodes is changed to a value of 0 V or less, and is changed from 0 V, which is the adopted value in Embodiment 2 described above. Operation conditions in a period before t6-3 and a period after t6-4 in FIG. 6 are the same as those in a period before t5-3 and a period after t5-4 in the plasma processing process (FIG. 5) according to Embodiment 2 described above. Therefore, the description thereof will be omitted.

As illustrated in FIG. 6, in the present development example, at a timing of t6-3, a total value of net applied voltages to electrostatic attraction electrodes from the direct current power supplies 12 and 13 is changed to a value of 0 V or less to be equal to a shift amount of a plasma potential of a wafer in the negative direction during the plasma discharge. To prevent the reduction of the electrostatic attraction force of the wafer, the applied voltage is set such that the potential difference between both electrodes is equal to or larger than 1000 V. Accordingly, a fluctuation of the plasma potential of the wafer can be canceled due to a change in the applied voltage to the electrostatic attraction electrode, a decrease in the attraction force of the wafer can be prevented, and the generation of positional deviation of the wafer can be prevented.

In the present embodiment, the total value of the net applied voltages to the electrostatic attraction electrodes during the period of the dechuck step from t5-4 to t5-6 is set to +600 V, which is the same as that in Embodiment 1 illustrated in FIG. 2, and a setting of the net applied voltage during the period from t5-4 to t5-6 may be the same value as a setting value during the period from t5-3 to t5-4. In this case, it is possible to prevent a rapid fluctuation of the attraction force caused by a change in the net applied voltage between steps including the plasma discharge step and the dechuck step, and it is possible to further prevent the generation of the positional deviation of the wafer.

For Embodiment 2 described above, an evaluation experiment on a particle adhesion number to the wafer after the plasma etching processing was performed. Existent Example 1 is used here as a comparison condition for level comparison of the number of adhering particles. As the experiment conditions, during the period of t3-1 to t3-6, the voltage values of the ESC voltage (+) and the ESC voltage (−) are set to +600 V and −600 V, respectively, and the potential difference between both electrodes is maintained at 1200 V. The other experiment conditions are the same as those of the above-described evaluation test in Embodiment 1, and therefore the description thereof will be omitted.

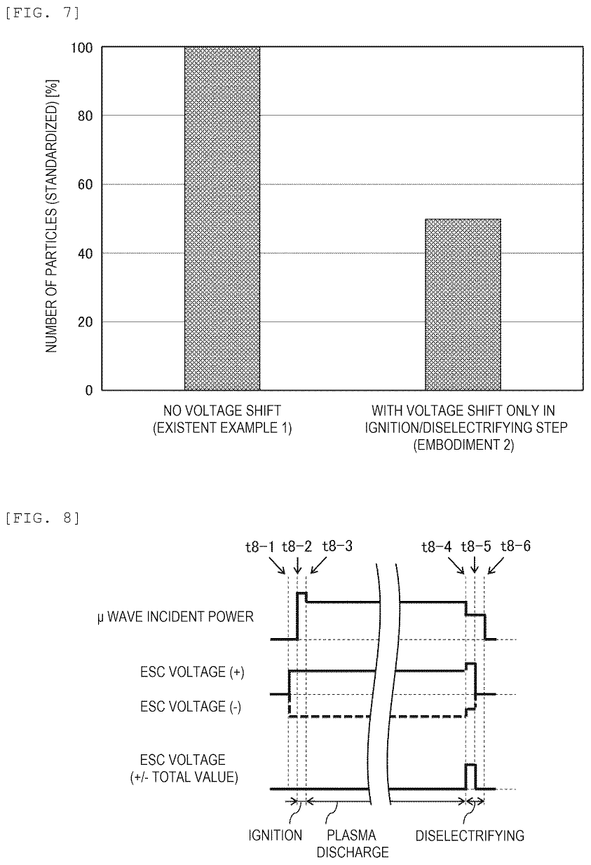

FIG. 7 illustrates a result of an investigation regarding an effect of reducing the particle adhesion to the wafer according to Embodiment 2. A vertical axis of FIG. 7 is a converted value of the number of adhering particles when the number of adhering particles in Existent Example 1 is standardized as 100%. As can be understood from the result, in the plasma processing process in FIG. 5 in which the total value of the net applied voltages applied to the electrostatic attraction electrodes is changed during t5-3 to t5-4, the number of particles can be reduced to about half as compared with that in Existent Example 1. Further, the present embodiment is more useful than Embodiment 1 in that it is possible to minimize the influence on changes in the plasma state.

### Embodiment 3

FIG. 8 is a time chart of processing according to Embodiment 3 of the invention. Embodiment 3 of the invention will be described while paying attention to a difference in configuration from Embodiment 1 and Embodiment 2. In FIG. 8, in a period from t8-1 to t8-3, a total value of net applied voltages to electrostatic attraction electrodes is changed to 0 V and is changed from +600 V, which is the adopted value in Embodiment 2 described above. An operation of each parameter in a period after t8-3 in FIG. 8 is the same as an operation of each parameter in a period after t5-3 in the plasma processing process (FIG. 5) according to Embodiment 2 described above. Therefore, the description thereof will be omitted.

In the present embodiment, as illustrated in FIG. 8, first, the applied voltage is changed such that the net applied voltage from the direct current power supplies 12 and 13 to the electrostatic attraction electrodes is 0 V at a timing of t8-1. In the present embodiment, to prevent the reduction of the electrostatic attraction force of the wafer, the voltage values of the ESC voltage (+) and the ESC voltage (−) are set to +600 V and −600 V, respectively, and a potential difference between both electrodes is maintained at 1200 V. Next, when the power of 1000 W is supplied from the radio frequency power supply 6 at a timing of t8-2 at which the plasma ignition step is started, the plasma is generated in the processing chamber by causing a current to flow through the solenoid coil 5. Subsequently, at a timing of t8-3 at which the plasma discharge step is started, the power supplied from the radio frequency power supply 6 is changed to 800 W, and the plasma etching processing is performed. In this way, by making the supply voltages from the direct current power supplies 12 and 13 constant during a period from t8-1 to t8-4, it is possible to prevent a rapid fluctuation of the attraction force caused by a change in the net applied voltage to the electrostatic attraction electrode, and it is possible to prevent the generation of the positional deviation of the wafer.

For Embodiment 3 described above, an evaluation experiment on a particle adhesion number to the wafer after the plasma etching processing was performed. Existent Example 1 is used here as a comparison condition for level comparison of the number of adhering particles. In addition, the experiment conditions are the same as those in the above-described evaluation test in Embodiment 2, and therefore description thereof will be omitted.

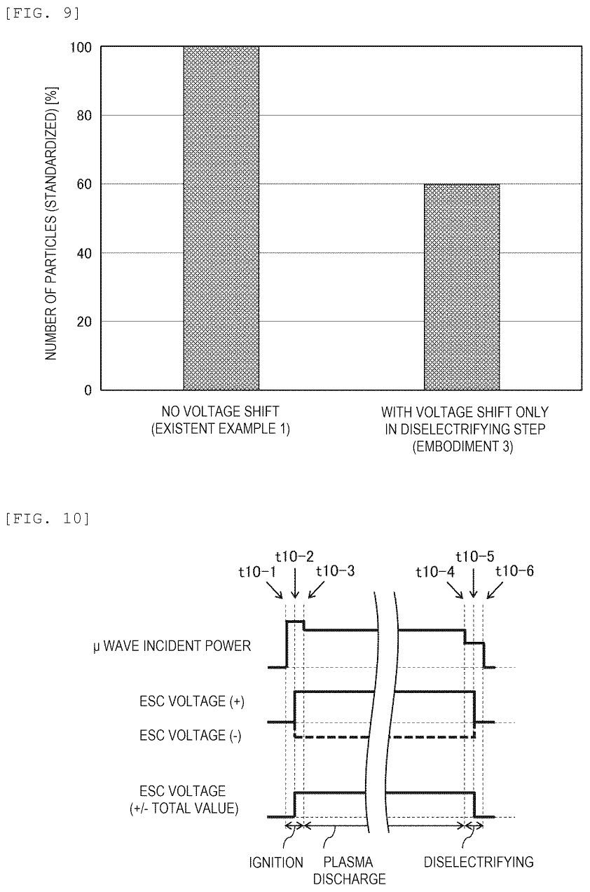

FIG. 9 illustrates a result of an investigation regarding an effect of reducing the particle adhesion to the wafer according to Embodiment 3. A vertical axis of FIG. 9 is a converted value of the number of adhering particles when the number of adhering particles in Existent Example 1 is standardized as 100%. As can be understood from the result, in the plasma processing process in FIG. 8 in which the net applied voltages applied to the electrostatic attraction electrodes are changed during t8-1 to t8-3, the number of particles can be reduced to 60% as compared with that in Existent Example 1. Further, Embodiment 3 has an advantage over Embodiments 1 and 2 in that it is possible to minimize the influence on a change in the plasma state and the attraction force of the wafer.

### Embodiment 4

FIG. 10 is a time chart of processing according to Embodiment 4 of the invention. The present embodiment will be described while paying attention to a difference in configuration from Embodiments 1 to 3. In FIG. 10, for a period from t10-1 to t10-2, a timing at which the ignition step is started is changed to be before the electrostatic attraction of the wafer is performed, and an order of implementation is opposite to that in Embodiment 1 described above. An operation of each parameter in a period after t10-2 in FIG. 10 is the same as an operation of each parameter after t2-2 in the plasma processing process (FIG. 2) according to Embodiment 1 of the invention described above. Therefore, the description thereof will be omitted.

As illustrated in FIG. 10, in the present embodiment, the power supply from the radio frequency power supply at a timing of t2-2 in FIG. 2 is started at a timing of t10-1, and a supply power amount is increased to 1000 W. Subsequently, at a timing t10-2, the supply of the applied voltage for the electrostatic attraction that is performed at the timing of t2-1 in FIG. 2 is started, and the control is performed such that the net applied voltages from the direct current power supplies 12 and 13 are +600 V. By changing the timing of wafer attraction in the plasma ignition step, since the formation of the plasma is performed before the potential of the wafer is changed, the plasma captures the charged particle that flies up from the back surface of the wafer when the supply of the applied voltage is started, and it is possible to further prevent the particle adhesion to the wafer.

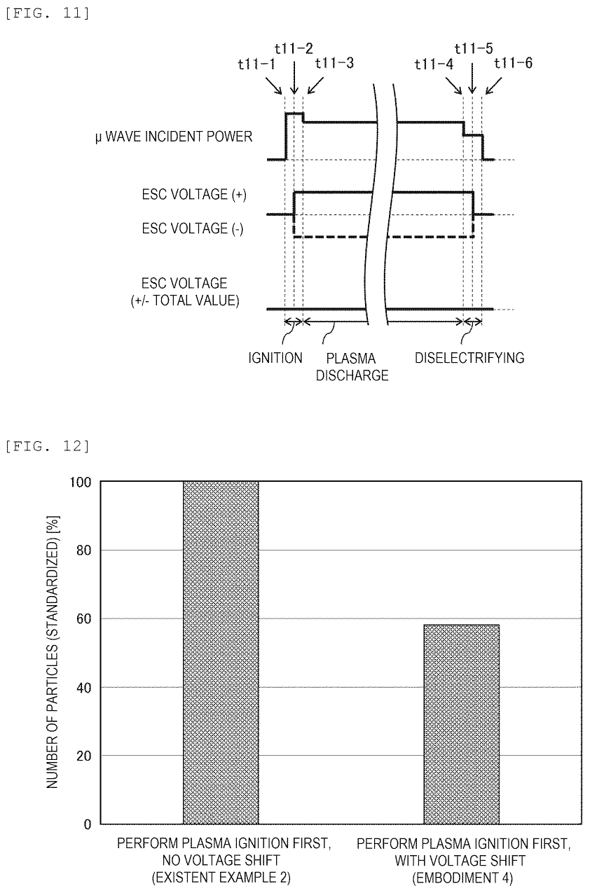

With respect to the above-described Embodiment 4, a plasma processing process in Existent Example 2 for level comparison of the particle reduction effect will be described. FIG. 11 illustrates a time chart of processing in the related art corresponding to Existent Example 2 which is an embodiment for comparing with Embodiment 4. Existent Example 2 is a plasma processing process in which during a period of t11-2 to t11-6, voltage values of the ESC voltage (+) and the ESC voltage (−) are set to +600 V and −600 V, respectively, and a net applied voltage to the electrostatic attraction electrodes is changed to 0 V.

For Embodiment 4 and Existent Example 2 described above, an evaluation experiment on a particle adhesion number to the wafer after the plasma etching processing was performed. In addition, the experiment conditions are the same as those in the above-described evaluation test in Embodiments 1 to 3, and therefore description thereof will be omitted.

FIG. 12 illustrates a result of an investigation regarding an effect of reducing the particle adhesion to the wafer according to Embodiment 4. A vertical axis of FIG. 12 is a converted value of the adhering particles when the number of adhering particles in Existent Example 2 is standardized as 100%. As can be understood from the result, in the plasma processing process in FIG. 10 in which the timing of the plasma formation is changed from t10-1 to t10-2, the number of particles can be reduced as compared with that in Existent Example 2 (0 V).

As described in the embodiments, it can be understood that in the plasma processing according to the invention, the net voltage applied to the electrostatic attraction electrodes is changed in the positive direction, and a control parameter for the wafer is maintained constant in the plasma etching step, whereby the adhesion of the particle to the wafer can be significantly reduced.

The net applied voltage to the electrostatic attraction electrodes can be changed in the positive direction by both or any one of the ignition step and the dechuck step, and by setting the net applied voltage to the electrostatic attraction electrodes in other steps to 0 V, it is possible to implement both prevention of the adhesion of particle and improvement of the stability of the wafer attraction force.

Further, by changing the timing at which the electrostatic attraction for the wafer is started from before the ignition step to during the ignition step, it is possible to reduce the adhesion of the filling-up particle caused by the rapid potential change of the wafer. As a synergistic effect of these effects, the invention can prevent the adhesion of the particle to the wafer and can improve the yield of device manufacturing.

According to the invention, the shift of the net applied voltage to the electrostatic attraction electrodes facing the wafer in the positive direction and the maintaining of the control parameter at a constant value in the plasma discharge step is established as defined in any one of FIGS. 2, 5, 6, 8, and 10, and the adhesion of particles can be prevented.

The invention is not limited to the embodiments described above and includes various modifications. For example, the embodiments described above have been described in detail to facilitate understanding of the invention, and the invention is not necessarily limited to those including all the configurations described above. A part of a configuration of a certain embodiment can be replaced with a configuration of another embodiment, and the configuration of another embodiment can be added to the configuration of a certain embodiment. A part of a configuration of each embodiment may be added to, deleted from, or replaced with another configuration. For example, in Embodiment 1 to 4 described above, the ignition step is performed first, but the invention is also established in a plasma processing process in which the ignition step is removed from each embodiment.

A part or all of processing configurations described above may be implemented by hardware by, for example, designing with an integrated circuit. Each of the processing configurations described above may be implemented by software by a processor interpreting and executing a program for implementing each function. Information such as a program, a table, and a file for implementing each function can be stored in a recording apparatus such as a memory, a hard disk, or a solid state drive (SSD), or in a recording medium such as an IC card, an SD card, or a DVD.

Control lines indicate what is considered to be necessary for the description, and not necessarily all control lines are always shown on a product. Actually, almost all configurations may be considered to be connected.

### REFERENCE SIGNS LIST

1: wafer
2: gate
3: processing chamber
4: sample stage
5: solenoid coil
6: radio frequency power supply
7: μ wave oscillation source
8: resonance unit
9: gas supply unit
10: first electrostatic attraction electrode
11: second electrostatic attraction electrode
12: first direct current power supply
13: second direct current power supply
14: control unit

1. A plasma processing apparatus comprising:
a processing chamber configured to allow a sample to be plasma-processed therein using plasma;
a radio frequency power supply configured to supply radio frequency power for generating the plasma;
a sample stage including an electrode to which a voltage for electrostatically attracting the sample is applied and configured to allow the sample to be placed thereon;
a direct current power supply configured to apply the voltage to the electrode; and
a control device configured to control the direct current power supply to apply a positive voltage to the electrode in a period from ignition of the plasma to when the sample is separated from the sample stage.

2. The plasma processing apparatus according to claim 1, wherein
the electrode includes a first electrode to which a first voltage for electrostatically attracting the sample is applied and a second electrode to which a second voltage for electrostatically attracting the sample is applied, and
a sum of the first voltage and the second voltage in a period of the plasma processing is positive.

3. The plasma processing apparatus according to claim 1, wherein
the voltage substantially has the same value in the period from the ignition of the plasma to when the sample is separated from the sample stage.

4. A plasma processing apparatus comprising:
a processing chamber configured to allow a sample to be processed therein using plasma;
a radio frequency power supply configured to supply radio frequency power for generating the plasma;
a sample stage including an electrode to which a voltage for electrostatically attracting the sample is applied and configured to allow the sample to be placed thereon;
a direct current power supply configured to apply the voltage to the electrode; and
a control device configured to control the direct current power supply to apply a positive voltage to the electrode in a period of processing for igniting the plasma or a period of processing for separating the sample from the sample stage.

5. The plasma processing apparatus according to claim 4, wherein
the voltage in a period of the plasma processing is 0 V or less, and
a magnitude of the voltage in the period of the plasma processing is equal to a shift amount of a plasma potential in the period of the plasma processing.

6. The plasma processing apparatus according to claim 1, wherein
the voltage before the ignition of the plasma is a positive value.

7. The plasma processing apparatus according to claim 1, wherein
the voltage after the ignition of the plasma and before a start of the plasma processing is a positive value.

8. A plasma processing method for plasma-processing, by plasma, a sample configured to be placed on a sample stage including an electrode to which a voltage for electrostatically attracting the sample is applied,
the plasma processing method comprising:
a step of applying a positive voltage to the electrode in a period from ignition of the plasma to when the sample is separated from the sample stage.

9. The plasma processing method according to claim 8, wherein
the electrode includes a first electrode to which a first voltage for electrostatically attracting the sample is applied and a second electrode to which a second voltage for electrostatically attracting the sample is applied, and
a sum of the first voltage and the second voltage in a period of the plasma processing is positive.

10. A plasma processing method for plasma-processing, by plasma, a sample configured to be placed on a sample stage including an electrode to which a voltage for electrostatically attracting the sample is applied,
the plasma processing method comprising:
a step of applying a positive voltage to the electrode in a period of processing for igniting the plasma or a period of processing for separating the sample from the sample stage.

11. The plasma processing apparatus according to claim 4, wherein
the voltage before the ignition of the plasma is a positive value.

12. The plasma processing apparatus according to claim 4, wherein
the voltage after the ignition of the plasma and before a start of the plasma processing is a positive value.
